(19) United States
(12) Patent Application Publication
(10) Pub. No.: US 2023/0281421 A1
(43) Pub. Date: Sep. 7, 2023

(54) Electric Circuit for an Electronic Chip Card Module with Colored Contacts and Method for Producing Same

(71) Applicant: Linxens Holding, Mantes-la-Jolie (FR)

(72) Inventors: Simon Vassal, Mantes-la-Jolie (FR); Catheline RAMSAMY, Mantes-la-Jolie (FR); Francois GREMION, Mantes-la-Jolie (FR); Nicolas MICHAUDET, Mantes-la-Jolie (FR)

(21) Appl. No.: 17/926,739

(22) PCT Filed: May 20, 2021
(86) PCT No.: PCT/EP2021/063535

§ 371 Date: Nov. 21, 2022

(30) Foreign Application Priority Data
May 21, 2020 (FR) FR2005396

(51) Int. Cl. G06K 19/077; H01L 23/498; H01L 23/14; H01L 21/48

(52) U.S. Cl. CPC G06K 19/07739; H01L 23/49855; G06K 19/07747; H01L 23/49838; H01L 23/142; H01L 21/4846

(57) ABSTRACT

The invention relates to an electrical circuit, for example of the printed circuit type, for producing a module intended to be integrated into a chip card. This module has electrical contact—or connector—areas for the connection and communication of the chip to and with a read/write system. In order to give them a different colour from the gilded or silvered ones generally used, these electrical contact areas are at least partially covered with a surface layer comprising a compound of XpOqNrCs type, in which X may be Hf, Ta, Zr, Nb, Mo, Cr, V, Ti or Sc, with p, q>0 and r≥0 and/or s≥0. The invention also relates to a method for manufacturing such an electrical circuit.

### TECHNICAL FIELD

The invention relates to the field of electrical circuits having contacts or conductive tracks of connectors.

### PRIOR ART

In the present document, an example of an application of the electrical circuit according to the invention is taken from the chip card field, but this example is readily transferable to other electrical circuit applications. Notably, the invention is particularly advantageous in all cases in which the conductive tracks are visible on the finished product as used by a consumer. For example, the production of coloured contacts for connectors of SD memory cards or USB sticks can also provide added aesthetic value.

A chip card has an electronic module with electrical contact—or connector—areas for the connection and communication of at least one electronic chip, attached to the module, to and with a read/write system.

Specifically, a chip card is generally constituted by a relatively rigid support, for example made of plastics material, constituting the main part of the card, in which a separately manufactured electronic module is incorporated. This electronic module has a generally flexible printed circuit provided with an electronic chip (integrated circuit) and connection—or connector—means constituted, for example, by contacts formed by conductive metal tracks flush with the electronic module, on the surface of the support.

Chip cards have multiple uses: credit cards, SIM cards for mobile telephones, travelcards, identity cards, etc.

As well as the need to have good electrical conduction between the contacts and the connector of a read/write device, chip card manufacturers now wish to match the colour of the contacts to the colour(s) of the card. For this purpose, the contacts are generally covered either with a layer of gold, in order to obtain a gilded finish, or with a layer of silver or palladium, in order to obtain a silvered finish.

In order to obtain more colours, it is possible to use a method as described in the document U.S. Pat. No. 6,259,035B1. This method relies on the use of solutions based on gold, palladium or silver in order to obtain a wider spectrum of colours. However, this type of method does not make it possible to obtain certain colours, notably a black or near-black colour.

It is an aim of the invention to provide electrical circuits with coloured contacts or conductive tracks, notably for example having a black or near-black colour, on at least part of the surface of the contacts or conductive tracks, while still preserving notably the electrical and mechanical properties suitable for establishing electrical connections.

### SUMMARY OF THE INVENTION

For this purpose, a method for manufacturing an electrical circuit, notably for producing chip card modules, is proposed, this method comprising the following steps:
providing a dielectric substrate with a sheet of electrically conductive material resting on the dielectric substrate,
depositing at least one layer of an electrically conductive material on the sheet of electrically conductive material, this layer of an electrically conductive material forming a surface layer covering at least one region of the surface of at least one conductive track, this conductive track being formed in the sheet of electrically conductive material.

In the course of this method, the formation of the surface layer includes a step of physical vapour deposition from at least one metal target, in the composition of which at least one of the metals in the following list is involved: chromium, hafnium, tantalum, zirconium, niobium, molybdenum, vanadium, titanium and scandium; and in an atmosphere comprising at least one of the following elements: argon, nitrogen and oxygen. Optionally, this atmosphere comprises argon, nitrogen and oxygen.

Specifically, by virtue of this type of physical vapour deposition, the inventors have been able to obtain a surface layer having not only a very dark colour that is close to black, or even black, but also an electrical conductivity and a robustness making it possible to fulfil the specifications required notably in the chip card field, and more particularly in the field of chip cards for banking applications. It has also been possible to obtain other colours for the surface layer by virtue of this type of physical vapour deposition.

This method includes one or more other ones of the following optional features, considered independently of one another or in combination with one or more others:
the surface layer is composed of a compound of XpOqNrCs type, with X included in the list constituted by Hf, Ta, Zr, Nb, Mo, Cr, V, Ti and Sc, and in which p and q are strictly positive and r and s are numbers at least one of which is greater than or equal to zero;
the surface layer is deposited on a bond layer, which itself is formed on the basis of physical vapour deposition in the atmosphere of a working gas comprising argon, in which at least one metal target is used, in the composition of which at least one of the metals in the following list is involved: chromium, hafnium, tantalum, zirconium, niobium, molybdenum, vanadium, titanium and scandium;
it comprises a step of laser etching the surface layer and the bond layer which are located between at least two conductive tracks, in order to disconnect these conductive tracks;
the bond layer and the surface layer are deposited on a conductive grid (that is to say, one used in the scope of leadframe technology) formed in the sheet of electrically conductive material in the course of steps prior to a step of transferring this grid to the dielectric substrate;
the surface layer is deposited selectively on at least one region of the surface of at least one conductive track in the course of a step during which the surface layer deposited on a support beforehand is transferred to the sheet of electrically conductive material with the aid of a laser; and
the method comprises a step of producing a mask, prior to the formation of the surface layer, in order to selectively deposit the surface layer only on certain regions of the sheet of electrically conductive material.

According to another aspect, an electrical circuit, notably for producing chip card modules, is proposed. For example, this electrical circuit is produced by virtue of the method mentioned above.

This circuit comprises:
a dielectric substrate with a sheet of electrically conductive material resting on the dielectric substrate,
at least one layer of an electrically conductive material resting directly or indirectly on the sheet of electrically conductive material, this layer of an electrically conductive material forming a surface layer covering at least one region of the surface of at least one conductive track, this conductive track being formed in the sheet of electrically conductive material.

In this circuit, the surface layer comprises a compound of XpOqNrCs type, with X included in the list constituted by Hf, Ta, Zr, Nb, Mo, Cr, V, Ti and Sc, and in which p and q are strictly positive and r and s are numbers at least one of which is greater than or equal to zero.

This stoichiometry of the layer makes it possible to obtain a coloured and conductive coating. The roughness of this layer can also contribute to giving it a more or less intense appearance (notably for the colour black) and more or less matte appearance.

Furthermore, this circuit may have one or more other ones of the following optional features, considered independently of one another or in combination with one or more others:
the surface layer comprises 30% to 65% by weight of at least one of the metals included in the following list: chromium, hafnium, tantalum, zirconium, niobium, molybdenum, vanadium, titanium and scandium, 0% to 40% by weight of nitrogen, 15% to 55% by weight of oxygen and 0% to 6% by weight of carbon;
it comprises a bond layer underlying the surface layer, this bond layer comprising at least one of the metals in the following list: chromium, hafnium, tantalum, zirconium, niobium, molybdenum, vanadium, titanium and scandium; and
it comprises a bond layer which has a thickness between 10 and 1000 nanometres; for example, the thickness of the bond layer is close to 700 nanometres if it comprises essentially titanium; the bond layer may, however, optionally have a smaller thickness, for example between 10 and 200 nanometres or even between 10 and 100 nanometres, and a surface layer which has a thickness between 100 and 2000 nanometres, for example this thickness is between 300 and 400 nanometres.

### BRIEF DESCRIPTION OF THE DRAWINGS

Other features, aims and advantages of the invention mentioned above will become apparent upon reading the following detailed description and with reference to the appended drawings, which are given by way of nonlimiting examples and in which:

FIG. 1 schematically shows, in perspective, a chip card having an example of a module according to the invention;

FIG. 2 schematically and partially shows, in section, an example of a connector for a chip card module as shown in FIG. 1;

FIG. 3 schematically shows a view from above of a portion of an electrical circuit for a connector of a chip card module as shown in FIG. 1;

FIG. 4 schematically shows various steps of multiple examples of embodiments of the method according to the invention.

### DETAILED DESCRIPTION

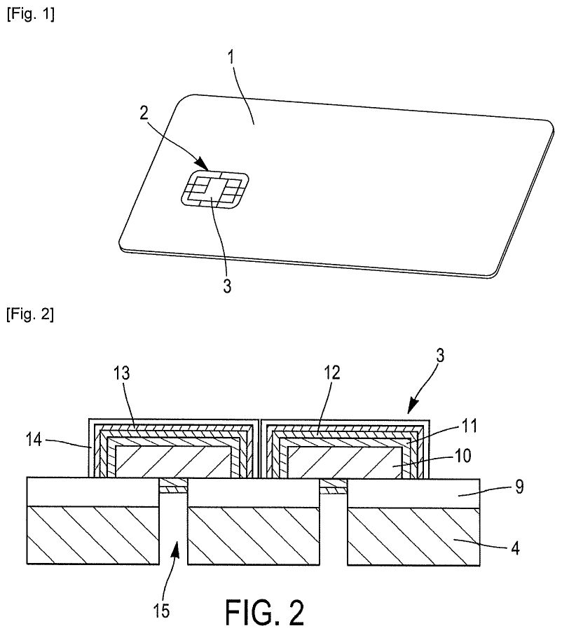

According to one example of an application of the electrical circuit according to the invention, which is illustrated by FIG. 1, a chip card 1 has a module 2 with a connector 3. The module 2 is generally produced in the form of a separate element which is inserted into a cavity formed in the body of the chip card 1. This element has a generally flexible dielectric substrate 4 (see FIG. 2) made of PET, epoxy glass or polyimide, etc., on which the connector 3, to which an electronic chip (not shown) is subsequently connected, is produced.

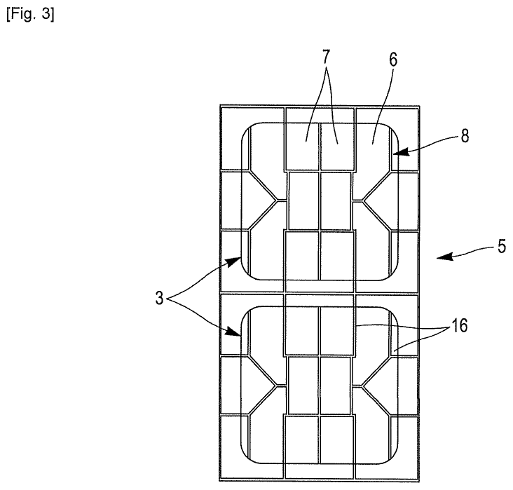

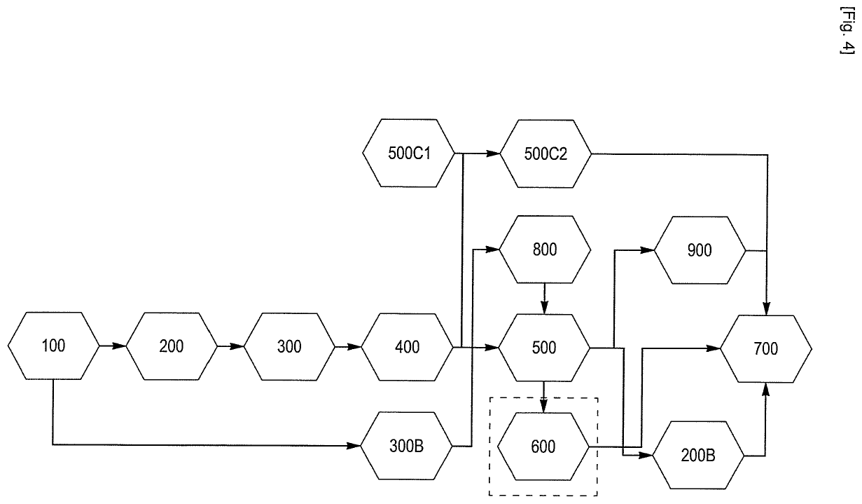

FIG. 3 illustrates an example of a portion of an electrical circuit 5 with two connectors 3. Each connector 3 comprises a contact area 8 formed by conductive tracks 6. In the example illustrated, eight electrical contacts 7 are produced from conductive tracks 6, on one face (single-face circuit). Optionally, other tracks and/or contacts may be produced on the other face if the connector corresponds to a double-face circuit.

More particularly, as shown in section in FIG. 2, a connector 3 (that is to say essentially a module without an electronic chip) has a multilayer structure formed by a dielectric substrate 4, a layer of adhesive 9, a sheet of electrically conductive material 10, a first intermediate layer 11, optionally a second intermediate layer 12, optionally a bond layer 13, and lastly a surface layer 14.

The dielectric substrate 4 is, for example, formed by a strip of epoxy glass having a thickness of 110 micrometres. The sheet of electrically conductive material 10 is, for example, formed by a sheet of copper or copper alloy with a thickness of micrometres. The first intermediate layer 11 is, for example, formed by an electrodeposited layer of nickel with a thickness of 1000 to 7000 nanometres. The second intermediate layer 12 is, for example, formed by a layer of electrodeposited palladium or gold with a thickness of 1 to 300 nanometres. More generally, the first and second intermediate layers 11, 12 are produced by electrodeposition, for example, and may comprise at least one of the metals included in the list comprising palladium, copper, aluminium, iron, gold and nickel.

The bond layer 13 is essentially composed of a metal layer comprising at least one of the following metals: chromium, hafnium, tantalum, zirconium, niobium, molybdenum, vanadium, titanium and scandium. This layer is vapour deposited. The surface layer 14 is essentially composed of a compound of XpOqNrCs type, with X included in the list constituted by Hf, Ta, Zr, Nb, Mo, Cr, V, Ti and Sc, and in which p and q are strictly positive and r and s are numbers at least one of which is greater than or equal to zero. This layer is also vapour deposited with 30% to 65% by weight of one of the metals in the following list: chromium, hafnium, tantalum, zirconium, niobium, molybdenum, vanadium, titanium and scandium, 0% to 40% by weight of nitrogen, 15% to 55% by weight of oxygen and 0% to 6% by weight of carbon. The bond layer 13 has for example a thickness between 10 and 1000 nanometres, and the surface layer 14 has for example a thickness between 100 and 1000 nanometres.

FIG. 4 schematically illustrates various steps of multiple examples of embodiments of the method according to the invention for manufacturing the connector 3. These steps comprise:
a step 100 of providing a sheet of electrically conductive material 10;
a step 200 comprising:

providing a substrate 4, for example made of epoxy glass, PET or polyimide,

coating one face of the substrate 4 with a layer of adhesive 9,

perforating the substrate 4 on which the layer of adhesive 9 rests in order to produce, through the substrate 4 and the layer of adhesive 9, connection wells 15 and optionally a cavity in which an electronic chip will subsequently be housed,

laminating the sheet of electrically conductive material 10 onto the substrate 4 coated with the layer of adhesive 9 and at least partially covering the connection wells and the cavity, and optionally crosslinking the layer of adhesive 9;
a photolithography step 300 in order to form conductive tracks 6 and/or contacts 7 in the sheet of electrically conductive material 10;
a step 400 of depositing the first 11 and the optional second 12 intermediate layers, for example by electrodeposition;
a step 500 of physical vapour deposition of the optional bond layer 13 and the surface layer 14;
a step 600 of laser etching the bond layer 13 and surface layer 14 over regions 16 (see FIG. 3) located between the contacts 7 so as to expose the substrate in these regions 16, in order to disconnect the conductive tracks 6 and the contacts 7 to one another; for this step, the laser has for example a spot of 12 to 35 micrometres in diameter, for a power of 1 to 15 watts and a spacing of 0 to 60 micrometres between each impact;
one or more steps 700 of transferring chips (for example one electronic chip per connector 3), individually separating the connectors 3, etc. from the electrical circuit obtained at the end of the previous steps, and carrying out the production of a module 2 and/or the finishing of a chip card 1 having such a module 2.

Alternatively, according to another embodiment of the method, it includes steps identical or similar to the steps 100 to 500. Between the steps 400 and 500, however, a step 800 comprising depositing a film of photosensitive resin on the electrodeposited layers 11 and 12 is carried out. This resin is exposed to radiation designed to pass through a mask, and then is developed so as to expose the conductive tracks 6 and the contacts 7 and to protect regions located between the conductive tracks 6 and the contacts 7. Thus, during the step 500 of physical vapour deposition of the optional bond layer 13 and the surface layer 14, these layers are deposited only in regions intended to be electrically conductive (conductive tracks 6 and the contacts 7). Of course, the resin that has protected the regions 16 located between the conductive tracks 6 and the contacts 7 during the step 500 of physical vapour deposition of the bond layer 13 and the surface layer 14 is subsequently removed during a step 900. For this step, for example, the attack solution could be acidic or basic, with a temperature between 15 and 50 degrees Celsius and a pressure of 1 to 5 bar.

Alternatively, according to yet another embodiment of the method, the sheet of electrically conductive material 10 provided in step 100 is cut out in a step 300B so as to form conductive tracks 6 and/or contacts 7 in the sheet of electrically conductive material 10. In other words, the step 300B makes it possible to produce a leadframe. Next, during a step 500, the optional bond layer 13 and the surface layer 14 are produced by physical vapour deposition on the leadframe. A step 200B is then carried out, comprising providing a substrate 4, for example made of epoxy glass, PET or polyimide, coating one face of the substrate 4 with a layer of adhesive 9, perforating the substrate 4 on which the layer of adhesive 9 rests in order to produce, through the substrate 4 and the layer of adhesive 9, connection wells 15 and optionally a cavity in which an electronic chip will subsequently be housed, laminating the leadframe onto the substrate 4 coated with the layer of adhesive 9 and at least partially covering the connection wells 15 and the cavity, and optionally crosslinking the layer of adhesive 9. The structure thus obtained may then undergo the step or steps 700 mentioned above. Step 600 is not necessary in this case since the optional bond layer 13 and the surface layer 14 have been deposited only on the leadframe and not on the substrate 4, as for the first embodiment described above. The leadframe may be cut out initially by a punch/die perforation tool in order that the conductive tracks 6 and the contacts 7 are properly isolated from one another.

According to yet another embodiment of the method, the steps 100 to 400 described above are carried out. In parallel, a step 500C1 of physical vapour deposition of the bond layer 13, on the one hand, and the surface layer 14, on the other hand, each on a support made of PET, for example, is carried out. Next, a step 500C2 of selective laser transfer is carried out so as to transfer the optional bond layer 13, then the surface layer 14, each on its PET support, to the regions intended to be covered with the conductive layer 14, that is to say essentially to the conductive tracks 6 and the contacts 7. For this step 500C2, the laser has a spot of 12 to 35 micrometres in diameter, for a power of 1 to 15 watts and a spacing of 0 to 60 micrometres between two impacts. One or more steps 700 as mentioned above can then subsequently be carried out in order to produce a module 2 and/or to finish a chip card 1 having such a module 2.

The physical vapour deposition of the surface layer 14 is carried out for example with the aid of a magnetron sputtering device using direct current, pulsed direct current, or radiofrequency current, with a power of 100 to 700 000 watts and a current density of 10 to 200 amperes per square metre. The deposition is carried out in a vacuum having a residual pressure of between 1 and 10·10⁻³ mbar.

Alternatively, this physical vapour deposition of the surface layer 14 may be performed with the aid of a thermal evaporation or cathodic arc physical vapour deposition (CAPVD) technique.

The physical vapour deposition of the surface layer 14 is carried out with argon as working gas at a flow rate of 100 to 600 standard cubic centimetres per minute (SCCM), 10 to 150 standard cubic centimetres per minute of nitrogen, 1 to 100 standard cubic centimetres per minute of oxygen and 1 to 20 standard cubic centimetres per minute of acetylene (if the carbon deposition mode uses a gas. This involves for example deposition aiming to obtain a surface layer 14 with a black or near-black colour—for other colours, acetylene is not always necessary).

The physical vapour deposition of the surface layer 14, whether this is done directly onto the conductive tracks 6 and the contacts 7 or onto a support before transfer to the conductive tracks 6 and the contacts 7, may also be carried out with the aid of a reactive physical vapour deposition method by using a stream of argon as working gas having a flow rate of 40 to 70 standard cubic centimetres per minute. In order to obtain a surface layer 14 with a black or near-black colour, the addition of carbon is carried out either with the aid of a graphite target sputtered under a stream of argon at a flow rate of 100 to 600 standard cubic centimetres per minute, or with an acetylene gas plasma having a flow rate of 1 to 20 standard cubic centimetres per minute. Furthermore, a plasma is formed with a gas mixture composed of nitrogen and oxygen during this sputtering procedure.

The conductive tracks 6 or contacts 7, with their surface layer 14, resulting from all these embodiments advantageously have a contact resistance of less than 500 milliohms and are highly resistant to the salt spray corrosion tests such as those required for chip cards used for banking applications.

According to the above-described alternative embodiments of the method, by using photosensitive resin masks it is possible to produce coloured patterns, such as logos (with the aid of the surface layer, and optionally the bond layer), on a yellow background (underlying layer of gold) or grey background (underlying layer of palladium, silver or nickel). Such patterns can be produced for the purpose of graphical personalization or protection against copying.

### EXAMPLES

### Example 1: Deposition in Black

Deposition of a surface layer 14 of XₚO_{q}NᵣCₛ is carried out by reactive physical vapour deposition (see above). This deposition is carried out, for example, with the aid of a sputtering device with a power of 4 kilowatts. This deposition is carried out on a titanium bond layer 13 of about 700 nanometres (itself resting on a copper substrate covered with nickel and then gold). This surface layer 14 constitutes about 300 to 400 nanometres. The deposition of this surface layer 14 is carried out with argon as working gas and in the presence notably of dinitrogen, dioxygen and carbon. This deposition is carried out in a vacuum having a residual pressure of close to 10⁻² mbar.

Measurements taken by energy dispersive spectroscopy (EDX), which do not make it possible to distinguish the composition of the surface layer from that of the bond layer 13, give the following respective concentrations by weight: titanium: 61.8%; oxygen: 17.5%; nitrogen: 16.7% and carbon: 4.0%.

The contact resistance obtained is less than 500 milliohms before and after a 24 h salt spray test according to the standard ISO9227.

The surface layer 14 resulting from this embodiment has a colorimetry with an index L* of less than 40 in the CIELAB colour space introduced by the organization IEC (International Commission on Illumination). Likewise, the indices a* and b* in this colour space are close to zero and less than 5 in terms of absolute value.

### Example 2: Deposition in Green or Blue

Deposition of a surface layer 14 of XpOqNrCs is carried out by PVD (physical vapour deposition). This deposition is carried out, for example, with the aid of a sputtering device (of magnetron type) with a power of 20 kilowatts. This deposition is carried out without a bond sublayer 13 of titanium. The surface layer 14 therefore rests directly on a copper substrate covered with nickel and then gold. This surface layer 14 constitutes about 50 to 100 nanometres. The deposition of this surface layer 14 is carried out with argon as working gas and in the presence of dinitrogen and dioxygen. This deposition is carried out in a vacuum having a residual pressure of close to 4.10-3 mbar.

Measurements taken by energy dispersive spectroscopy give the following respective concentrations by weight:
a) for green: titanium: 62%; oxygen: 38%; nitrogen: present in the form of traces.
b) for blue: titanium: 51%; oxygen: 49%; nitrogen: present in the form of traces.

The contact resistance obtained is less than 500 milliohms in all these cases.

1. Electrical circuit having electrical contacts, notably for producing chip card modules, comprising:
a dielectric substrate with a sheet of electrically conductive material resting on the dielectric substrate,
at least one layer of an electrically conductive material resting directly or indirectly on the sheet of electrically conductive material, this layer of an electrically conductive material forming a surface layer covering at least one region of the surface of at least one conductive track, this conductive track being formed in the sheet of electrically conductive material and being configured to form the electrical contacts,
characterized in that the surface layer comprises a compound of XpOqNrCs type, with X included in the list constituted by Hf, Ta, Zr, Nb, Mo, Cr, V, Ti and Sc, and in which p and q are strictly positive and r and s are numbers at least one of which is greater than or equal to zero.

2. Electrical circuit according to claim 1, wherein the surface layer comprises 30% to 65% by weight of at least one of the metals included in the list constituted by Hf, Ta, Zr, Nb, Mo, Cr, V, Ti or Sc, 0% to 40% by weight of nitrogen, 15% to 55% by weight of oxygen and 0% to 6% by weight of carbon.

3. Electrical circuit according to claim 1, comprising a bond layer underlying the surface layer, this bond layer comprising at least one of the metals in the following list: chromium, hafnium, tantalum, zirconium, niobium, molybdenum, vanadium, titanium and scandium.

4. Electrical circuit according to claim 3, comprising a bond layer having a thickness between 10 and 1000 nanometres and a surface layer having a thickness between 100 and 2000 nanometres.

5. Electrical circuit according to claim 1, wherein X═Ti.

6. Chip card comprising a card body and a module inserted in a cavity formed in the card body, this module comprising a connector comprising an electrical circuit according to claim 1.

7. Manufacturing method specially designed for the manufacture of an electrical circuit according to claim 1, this method comprising the following steps:
providing a dielectric substrate with a sheet of electrically conductive material resting on the dielectric substrate,
depositing at least one layer of an electrically conductive material on the sheet of electrically conductive material, this layer of an electrically conductive material forming a surface layer covering at least one region of the surface of at least one conductive track, this conductive track being formed in the sheet of electrically conductive material and being configured to form the electrical contacts,
characterized in that the formation of the surface layer includes a step of physical vapour deposition from at least one metal target, in the composition of which at least one of the metals in the following list is involved: chromium, hafnium, tantalum, zirconium, niobium, molybdenum, vanadium, titanium and scandium, and in the atmosphere of a gas comprising at least one of the following elements: argon, nitrogen and oxygen.

8. Method according to claim 7, wherein the surface layer comprises a compound of XpOqNrCs type, with X included in the list constituted by Hf, Ta, Zr, Nb, Mo, Cr, V, Ti and Sc, and in which p and q are strictly positive and r and s are numbers at least one of which is greater than or equal to zero.

9. Method according to claim 7 or 8, wherein the surface layer is deposited on a bond layer, which itself is formed from physical vapour deposition in the atmosphere of a working gas comprising argon, in which at least one metal target is used, in the composition of which at least one of the metals in the following list is involved: chromium, hafnium, tantalum, zirconium, niobium, molybdenum, vanadium, titanium and scandium.

10. Method according to claim 9, comprising a step of laser etching the surface layer and the bond layer which are located between at least two conductive tracks, in order to disconnect these conductive tracks.

11. Method according to claim 9, wherein the bond layer and the surface layer are deposited on a leadframe formed in the sheet of electrically conductive material, in the course of steps prior to a step of transferring this leadframe to the dielectric substrate.

12. Method according to one of claims 7 to 9 claim 7, wherein the surface layer is deposited selectively in at least one region of the surface of at least one conductive track in the course of a step during which the surface layer deposited on a support beforehand is transferred to the sheet of electrically conductive material with the aid of a laser.

13. Method according to one of claims 7 to 12 claim 7, comprising a step of producing a mask, prior to the formation of the surface layer, in order to selectively deposit the surface layer only in certain regions of the sheet of electrically conductive material.
